(19) United States
(12) Patent Application Publication
(10) Pub. No.: US 2026/0331602 A1
(43) Pub. Date: Oct. 22, 2026

(54) WIRELESS MICROSYSTEM FOR PERFORMING REAL-TIME MONITORING ON IN-SITU PRESSURE AND TEMPERATURE INSIDE LITHIUM BATTERY AND MANUFACTURING METHOD THEREOF

(71) Applicant: Ningbo University, Ningbo (CN)

(72) Inventors: Xiaopeng CHEN, Ningbo (CN); Sijia LING, Ningbo (CN); Shengkang LU, Ningbo (CN); Jiawen YIN, Ningbo (CN); Jiawen JIAN, Ningbo (CN); Qinghui JIN, Ningbo (CN)

(21) Appl. No.: 18/873,293

(22) PCT Filed: Mar. 19, 2024
(86) PCT No.: PCT/CN2024/082344

§ 371 Date: Dec. 9, 2024

(30) Foreign Application Priority Data
Nov. 22, 2023 (CN) 202311559093.7

(51) Int. Cl. H01M 10/42; H01M 10/0525; H01M 10/48; H03H 9/13; H03H 9/15; H03H 9/17; H04B 11/00

(52) U.S. Cl. CPC H01M 10/4257; H01M 10/0525; H01M 10/486; H03H 9/13; H03H 9/17; H04B 11/00; H01M 2010/4278; H03H 2009/155

(57) ABSTRACT

A wireless microsystem for performing real-time monitoring on in-situ pressure and temperature inside a lithium battery comprises an acoustic wave receiving module, a working condition sensing module, and an acoustic wave transmitting module manufactured based on Micro-Electro-Mechanical System (MEMS) technology and connected sequentially; which can be non-destructively implanted into various lithium batteries; the acoustic wave receiving module is configured to, based on a first acoustic wave signal received from an external acoustic wave transmitter and corresponding to a first preset resonant frequency, perform acoustic-electric signal conversion to obtain a first electrical signal; the working condition sensing module couples an in-situ working state inside the cell to the first electrical signal to obtain a second electrical signal; the acoustic wave transmitting module is configured to perform electric-acoustic signal conversion on an electrical signal component satisfying a preset resonant frequency in the second electrical signal to transmit a second acoustic wave signal.

### TECHNICAL FIELD

The present disclosure provides the technological field of sensors and microsystems and in particular to a wireless microsystem for performing real-time monitoring on in-situ pressure and temperature inside a lithium battery and a manufacturing method thereof.

### BACKGROUND

Lithium ion batteries also called lithium batteries have the advantages of high energy density, long cycle life, no memory effect and good safety level and the like. The lithium batteries are widely applied in the aspects such as portable electronic products and electric vehicles. But the endurance and safety problems of the lithium batteries are always an obstacle in its application processes. Specifically, in order to improve the charge and discharge efficiency, ensure safe operation of system and lower the operation costs of system, it is required to accurately sense a working state of the lithium batteries. Those lithium batteries in abnormal state may affect the stability and safety of the system in the form of capacity reduction, increased heat and swelling and expansion and the like. Especially for a complex system formed by series or parallel-connection of multiple cells, the state difference between cells will not only accelerate the attenuation of the capacity of the battery pack but even also induce serious safety problems such as thermal runaway and the like due to excessive charge or discharge rate or excessive charge or discharge of individual batteries. At present, the following three manners are mainly employed to control the lithium batteries.

In a first manner, external characteristics such as a temperature, a voltage, a current and an internal resistance and so on of a surface of a lithium battery can be monitored to assess a working condition of the battery. But the information is only obtained from the level of device. Essentially, the lithium battery is an airtight complex system and it takes some time to transfer the changes of the features such as temperature, and pressure and the like resulting from the chemical reactions in the battery from inside the battery to outside the battery and therefore, it is difficult to accurately know the working state of the lithium battery relying only on the monitored external feature information.

In a second manner, an optical fiber Fabry-Perot sensor or an optical fiber Bragg grating sensor is inserted into a lithium battery to penetrate through a center of cells so as to realize monitoring on the working condition inside the lithium battery. But this penetration-type placement method is not applicable to the application scenarios of lithium battery packs in the new energy vehicles and the like in addition to having the disadvantages of high costs and difficult maintenance.

In a third manner, a commercial pressure sensor is custom-embedded into a large-volume prismatic lithium battery to lead out a pressure signal with a lead wire, so as to realize measurement on the internal pressure of the lithium battery during a charge and discharge process. But this invasive implanting method is not easily applied to a small-volume cylindrical lithium battery, and also has great impact on the performance of the battery.

Therefore, at present, it is urgent to design a wireless sensing microsystem technical solution for performing in-situ online monitoring on a working state inside a lithium battery to obtain a smart battery capable of self-sensing an internal working state.

### SUMMARY

In order to address the above problems, the present disclosure provides a wireless microsystem for performing real-time monitoring on in-situ pressure and temperature inside a lithium battery and a manufacturing method. The wireless microsystem can be non-destructively implanted into various lithium batteries to realize wireless energy input and real-time output of in-situ working state, helping monitor the state of the cells of the lithium batteries in real time and promoting practical application in productions.

In order to address the above issues, the present disclosure provides a wireless microsystem for performing real-time monitoring on in-situ pressure and temperature inside a lithium battery, which is applied inside a cell. The wireless microsystem for performing real-time monitoring on in-situ pressure and temperature inside the lithium battery comprises an acoustic wave receiving module, a working condition sensing module, and an acoustic wave transmitting module manufactured based on Micro-Electro-Mechanical System (MEMS) technology;
the acoustic wave receiving module, the working condition sensing module and the acoustic wave transmitting module are sequentially connected;
the acoustic wave receiving module is configured to, based on a first acoustic wave signal received from an external acoustic wave transmitter and corresponding to a first preset resonant frequency, perform acoustic-electric signal conversion to obtain a first electrical signal;
the working condition sensing module is configured to couple an in-situ working state inside the cell to the first electrical signal to obtain a second electrical signal;
the acoustic wave transmitting module is configured to perform electric-acoustic signal conversion on an electrical signal component satisfying a preset resonant frequency in the second electrical signal to transmit a second acoustic wave signal such that an external acoustic wave receiver determines the in-situ working state based on the received second acoustic wave signal, where the first preset resonant frequency is different from the second preset resonant frequency.

The present disclosure has the following beneficial effects: the wireless microsystem can be non-destructively implanted into various lithium batteries so as to effectively sense the in-situ working state inside the cells; the difference between the first preset resonant frequency and the second preset resonant frequency guarantees that the acoustic wave transmitting module is free from interference of the first acoustic wave signal and helps the subsequent determination of the in-situ working state, realizing wireless energy input and real-time output of the in-situ working state, helping perform real-time monitoring on the state of the cells in the lithium batteries and helping practical production applications.

Furthermore, the acoustic wave receiving module is an acoustic wave transducer which comprises structural subunits, and the structural subunits comprise an upper electrode layer, a first piezoelectric film and a lower electrode layer arranged sequentially from top down.

The second preset resonant frequency is determined based on a geometric size of the first piezoelectric film and a thickness of the structural subunits such that the second preset resonant frequency is different from the first preset resonant frequency.

In this solution, simulation is performed by adjusting the geometric size of the first piezoelectric film and the thickness of the structural subunits, so as to effectively determine the second preset resonant frequency, which ensures the second preset resonant frequency is different from the first preset resonant frequency. Therefore, the setting of the second preset resonant frequency helps signal separation and processing.

Furthermore, the structural subunits are connected sequentially to form an array structure of N*M, where N is an integer greater than 1 and M is an integer greater than 1, and N*M=a total number of the structural subunits.

In this solution, with the above setting, a larger first electrical signal can be obtained, which improves the efficiency of the acoustic-electric signal conversion.

Furthermore, the first acoustic wave signal is an acoustic wave signal consistent with a first-order mode resonant frequency of the first piezoelectric film.

In this solution, with the above setting, effective feed-in of the first acoustic wave signal can be realized.

Furthermore, the working condition sensing module comprises a second piezoelectric film and a pressure-sensitive sensing module arranged on the second piezoelectric film to sense the in-situ pressure condition inside the cell, and/or, a heat-sensitive sensing module to sense the in-situ temperature condition inside the cell; and when the working condition sensing module comprises the pressure-sensitive sensing module and the heat-sensitive sensing module, the pressure-sensitive sensing module and the heat-sensitive sensing module are in parallel connection.

In this solution, with the above setting, it can be guaranteed that the temperature and/or pressure condition inside the cell can be effectively sensed in time so that a corresponding solution can be used subsequently.

Furthermore, the heat-sensitive sensing module comprises a first circuit structure formed by multiple heat-sensitive resistors with a resistance value changing along with the temperature inside the cell such that the second electrical signal can be changed along with the temperature inside the cell.

In this solution, the first circuit structure formed by multiple heat-sensitive resistors reliably couples the temperature condition inside the cell to the first electrical signal so as to obtain the second electrical signal.

Furthermore, the pressure-sensitive sensing module comprises a second circuit structure formed by multiple pressure-sensitive resistors with a resistance value changing along with the pressure inside the cell such that the second electrical signal can be changed along with the pressure inside the cell.

In this solution, the second circuit structure formed by multiple pressure-sensitive resistors can reliably couple the pressure condition inside the cell to the first electrical signal so as to obtain the second electrical signal.

Furthermore, the second circuit structure comprises a first pressure-sensitive resistor, a second pressure-sensitive resistor, a third pressure-sensitive resistor and a fourth pressure-sensitive resistor.

An end of the first pressure-sensitive resistor is respectively connected to an end of the second pressure-sensitive resistor and a first input end of the acoustic wave transmitting module, and the other end of the first pressure-sensitive resistor is respectively connected to an end of the third pressure-sensitive resistor and a first output end of the acoustic wave receiving module.

The other end of the second pressure-sensitive resistor is respectively connected to an end of the fourth pressure-sensitive resistor and a second output end of the acoustic wave receiving module, and the other end of the fourth pressure-sensitive resistor is respectively connected to the other end of the third pressure-sensitive resistor and a second input end of the acoustic wave transmitting module.

In this solution, the second circuit structure uses a full-bridge piezoresistive structure and can be simply and reliably implemented.

The present disclosure further provides a manufacturing method of a wireless microsystem for performing real-time monitoring on in-situ pressure and temperature inside a lithium battery. The method is used to manufacture the above wireless microsystem for performing real-time monitoring on in-situ pressure and temperature inside the lithium battery. The method comprises the following steps:
based on MEMS technology, manufacturing the acoustic wave receiving module for performing acoustic-electric signal conversion by using the first piezoelectric film;
based on MEMS technology, arranging a sensing structure for sensing a working state of a cell on the second piezoelectric film to obtain the working condition sensing module;
based MEMS technology, manufacturing the acoustic wave transmitting module for performing electric-acoustic signal conversion by using a third piezoelectric film and arranging and connecting the acoustic wave receiving module, the working condition sensing module and the acoustic wave transmitting module sequentially and then embedding into the cell.

The present disclosure realizes wireless energy input and real-time output of the in-situ working state, which helps perform real-time monitoring on the state of the cells of the lithium battery and helps practical production applications.

### BRIEF DESCRIPTIONS OF THE DRAWINGS

FIG. 1 is a structural schematic diagram illustrating a wireless microsystem for performing real-time monitoring on in-situ pressure and temperature inside a lithium battery according to an embodiment of the present disclosure.

FIG. 2 is another structural schematic diagram illustrating a wireless microsystem for performing real-time monitoring on in-situ pressure and temperature inside a lithium battery according to an embodiment of the present disclosure.

FIG. 3 is a structural schematic diagram illustrating a pressure-sensitive sensing module according to an embodiment of the present disclosure.

FIG. 4 is an equivalent circuit diagram illustrating a full-bridge piezoresistive structure according an embodiment of the present disclosure.

FIG. 5 is a simplified diagram illustrating a first acoustic wave signal according to an embodiment of the present disclosure.

FIG. 6 is a simplified diagram illustrating a second electrical signal according an embodiment of the present disclosure.

FIG. 7 is a simplified diagram illustrating a second acoustic wave signal according to an embodiment of the present disclosure.

FIG. 8 is a schematic diagram illustrating harmonic superimposition of a square wave signal according to an embodiment of the present disclosure.

FIG. 9 is a flowchart illustrating a manufacturing method of a wireless microsystem for performing real-time monitoring on in-situ pressure and temperature inside a lithium battery according to an embodiment of the present disclosure.

Numerals of drawings are described below:

1. acoustic wave receiving module, 2. working condition sensing module, 3. acoustic wave transmitting module, 21. second piezoelectric film, R1. first pressure-sensitive resistor, R2. second pressure-sensitive resistor, R3. third pressure-sensitive resistor, R4. fourth pressure-sensitive resistor, 11. structural subunit in the acoustic wave receiving module, 111. first piezoelectric film in the structural subunit in the acoustic wave receiving module, and 31. structural subunit in the acoustic wave transmitting module.

### DETAILED DESCRIPTIONS OF EMBODIMENTS

In order to make the above objects, features, and advantages of the present disclosure clearer and more intelligible, the specific embodiments of the present disclosure will be further detailed below with drawings.

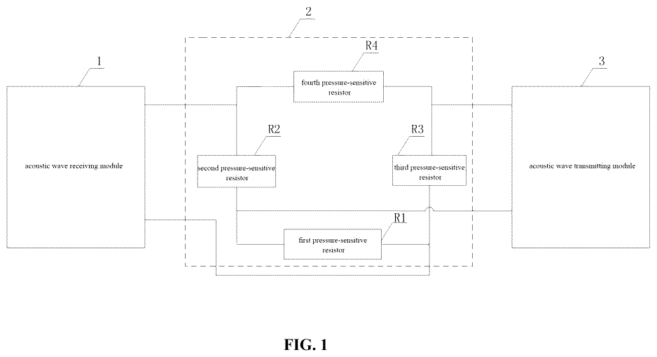

With reference to FIG. 1, it is a structural schematic diagram illustrating a wireless microsystem for performing real-time monitoring on in-situ pressure and temperature inside a lithium battery according to the present disclosure.

The present disclosure provides an embodiment in which a wireless microsystem for performing real-time monitoring on in-situ pressure and temperature inside a lithium battery is applied inside a cell. The wireless microsystem for performing real-time monitoring on in-situ pressure and temperature inside the lithium battery comprises an acoustic wave receiving module 1, a working condition sensing module 2 and an acoustic wave transmitting module 3 manufactured based on MEMS technology.

The acoustic wave receiving module 1, the working condition sensing module 2 and the acoustic wave transmitting module 3 are sequentially connected.

The acoustic wave receiving module 1 is configured to, based on a first acoustic wave signal received from an external acoustic wave transmitter and corresponding to a first preset resonant frequency, perform acoustic-electric signal conversion to obtain a first electrical signal.

The working condition sensing module 2 is configured to couple an in-situ working state inside the cell to the first electrical signal to obtain a second electrical signal.

The acoustic wave transmitting module 3 is configured to perform electric-acoustic signal conversion on an electrical signal component satisfying a preset resonant frequency in the second electrical signal to transmit a second acoustic wave signal such that an external acoustic wave receiver determines the in-situ working state based on the received second acoustic wave signal, where the first preset resonant frequency is different from the second preset resonant frequency.

In this embodiment, considering the lithium battery is a good conductor and its shell is made of metal material, the traditional method of electromagnetic induction wireless coupling energy is not applicable any longer. Therefore, it is urgent to seek a wireless sensing microsystem for performing in-situ online monitoring on a working state inside a lithium battery so as to provide a key technology basis for constructing a smart battery capable of self-sensing a working state inside a battery. For this purpose, the present disclosure provides a wireless microsystem for performing real-time monitoring on in-situ pressure and temperature inside a lithium battery. The wireless microsystem comprises an acoustic wave receiving module 1, a working condition sensing module 2 and an acoustic wave transmitting module 3 which are sequentially arranged and connected, and manufactured based on Micro Electro Mechanical System (MEMS) technology. The MEMS technology combining the traditional semiconductor technologies such as lithography and corrosion and the like with ultra-precision machining can, based on functional requirements, integrate microcircuits with micromechanics so as to realize miniaturization and batch production of to-be-processed devices, greatly improving the consistent performances of the to-be-processed devices and reducing the production costs while increasing the spatial density and coverage of the data detection. Based on the MEMS technology, the acoustic wave receiving module 1, the working condition sensing module 2 and the acoustic wave transmitting module 3 can be manufactured.

Specifically, the wireless microsystem is disposed inside a cell, and the working state sensing module 2 can sense an in-situ working state in the cell and couple the in-situ working state to the first electrical signal so as to obtain the second electrical signal. The in-situ working state may be a temperature state or a pressure state. The first acoustic wave signal comprises but not limited to an ultrasonic square wave signal.

In conclusion, the present disclosure provides a wireless microsystem for performing real-time monitoring on an in-situ pressure and temperature inside a lithium battery, which can be non-destructively implanted into various lithium batteries, so as to effectively sense the in-situ working state inside the cell. The difference between the first preset resonant frequency and the second preset resonant frequency guarantees that the acoustic wave transmitting module 3 is free from interference of the first acoustic wave signal and helps the subsequent determination of the in-situ working state, realizing wireless energy input and real-time output of the in-situ working state, helping perform real-time monitoring on the state of the cells in the lithium batteries and helping practical production applications.

As a preferred embodiment, the acoustic wave receiving module 1 is an acoustic wave transducer which comprises structural subunits 11, and the structural subunits 11 comprise an upper electrode layer, a first piezoelectric film 111 and a lower electrode layer arranged sequentially from top down.

The second preset resonant frequency is determined based on a geometric size of the first piezoelectric film 111 and a thickness of the structural subunits 11 such that the second preset resonant frequency is different from the first preset resonant frequency.

In this embodiment, simulation is performed by adjusting the geometric size of the first piezoelectric film 111 and the thickness of the structural subunits 11, so as to effectively determine the second preset resonant frequency. The second preset resonant frequency specifically corresponds to a first-order mode resonant frequency of a third piezoelectric film in the acoustic wave transmitting module 3. Therefore, the difference between the first preset resonant frequency and the second preset resonant frequency means a difference between the first-order mode resonant frequency of the first piezoelectric film 111 in the acoustic wave receiving module 1 and the first-order mode resonant frequency of the third piezoelectric film in the acoustic wave transmitting module 3, which ensures the acoustic wave transmitting module 3 is free from the interference of the first acoustic wave signal and helps more in subsequent signal separation so as to determine the in-situ working state.

Besides, the acoustic wave receiving module 1 essentially is hundred-micron-level acoustic wave transducer with its working principle shown below: excited by the first acoustic wave signal, it performs vibration under a bending mode so as to generate a bending moment in the first piezoelectric film 111 and hence generate a mechanical stress and further convert the stress into a charge to obtain the first electrical signal, realizing conversion of acoustic signal to electrical signal.

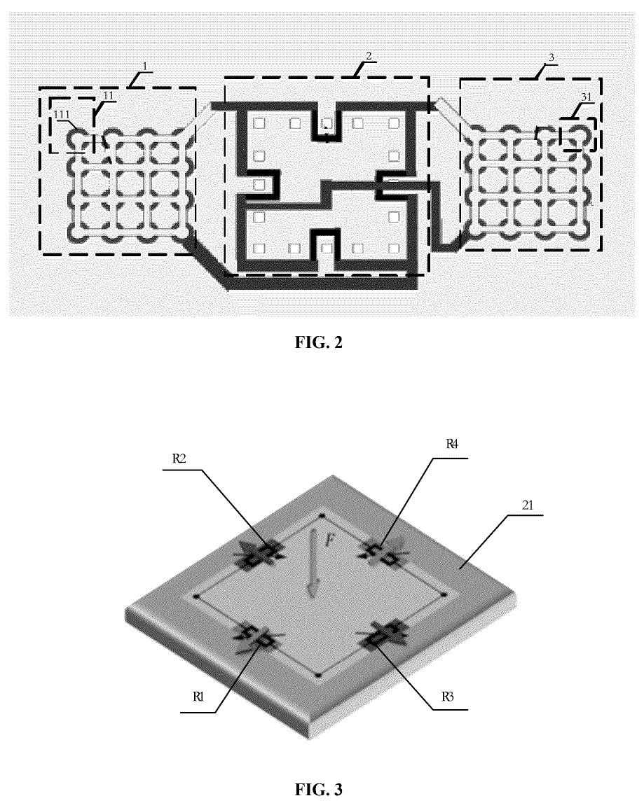

It should be further noted that, with reference to FIG. 2, it shows the acoustic wave receiver comprises 16 structural subunits. To avoid disorderly line connection, descriptions are made only with the structural subunit 11 at the upper left corner. It can be seen that the first piezoelectric film 111 in the structural subunit 11 is specifically circular (the dark-color circle in FIG. 2). The above geometric size specifically refers to a diameter of the circular first piezoelectric film 111.

As a preferred embodiment, the structural subunits are connected sequentially to form an array structure of N*M, where N is an integer greater than 1 and M is an integer greater than 1, and N*M=a total number of the structural subunits.

Specifically, the array structure is connected as shown in FIG. 2. In FIG. 2, descriptions are made with N=4 and M=4 as example. This setting helps obtain a larger first electrical signal and helps improve the efficiency of the acoustic-electric signal conversion.

As a preferred embodiment, the first acoustic wave signal is an acoustic wave signal consistent with the first-order mode resonant frequency of the first piezoelectric film 111.

In this solution, the first preset resonant frequency specifically is the first-order mode resonant frequency of the first piezoelectric film 111; it can be understood that the acoustic wave transmitting module 3 comprises a third piezoelectric film. After the second preset resonant frequency is determined, the third piezoelectric film with the first-order mode resonant frequency being the second preset resonant frequency is selected and made into the above acoustic wave transmitting module 3 based on MEMS technology.

Furthermore, similar to the acoustic wave receiving module 1, the acoustic wave transmitting module 3 also can be composed of multiple structural subunits 31 to form an array structure of 4*4 as shown in FIG. 2. The working principle of the acoustic wave transmitting module 3 is shown below: when the second electrical signal is applied, the third piezoelectric film may vibrate due to inverse piezoelectric effect to convert the third electrical signal into the second acoustic wave signal, so as to realize conversion of electrical signal to acoustic signal.

As a preferred embodiment, the working condition sensing module 2 comprises a second piezoelectric film and a pressure-sensitive sensing module arranged on the second piezoelectric film to sense the in-situ pressure condition inside the cell, and/or, a heat-sensitive sensing module to sense the in-situ temperature condition inside the cell; and when the working condition sensing module 2 comprises the pressure-sensitive sensing module and the heat-sensitive sensing module, the pressure-sensitive sensing module and the heat-sensitive sensing module are in parallel connection.

In this embodiment, with the above setting, it can be guaranteed that the temperature and/or pressure condition inside the cell can be effectively sensed in time so that a corresponding solution can be used subsequently.

As a preferred embodiment, the heat-sensitive sensing module comprises a first circuit structure formed by multiple heat-sensitive resistors with a resistance value changing along with the temperature inside the cell such that the second electrical signal can be changed along with the temperature inside the cell.

In this solution, considering the characteristics of the heat-sensitive resistors having a resistance value changing along with temperature, the first circuit structure formed by the heat-sensitive resistors can reliably couple the temperature condition in the cell to the first electrical signal so as to obtain the second electrical signal. It should be further noted that the first circuit structure comprises but not limited to the full-bridge disposal structure and is not specifically limited herein and thus can be flexibly disposed.

As a preferred embodiment, the pressure-sensitive sensing module comprises a second circuit structure formed by multiple pressure-sensitive resistors with a resistance value changing along with the pressure inside the cell such that the second electrical signal can be changed along with the pressure inside the cell.

In this solution, the second circuit structure formed by the pressure-sensitive resistors can reliably couple the pressure condition in the cell to the first electrical signal so as to obtain the second electrical signal.

As a preferred embodiment, the second circuit structure comprises a first pressure-sensitive resistor R1, a second pressure-sensitive resistor R2, a third pressure-sensitive resistor R3 and a fourth pressure-sensitive resistor R4.

An end of the first pressure-sensitive resistor R1 is respectively connected to an end of the second pressure-sensitive resistor R2 and a first input end of the acoustic wave transmitting module, and the other end of the first pressure-sensitive resistor R1 is respectively connected to an end of the third pressure-sensitive resistor R3 and a first output end of the acoustic wave receiving module 1.

The other end of the second pressure-sensitive resistor R2 is respectively connected to an end of the fourth pressure-sensitive resistor R4 and a second output end of the acoustic wave receiving module 1, and the other end of the fourth pressure-sensitive resistor R4 is respectively connected to the other end of the third pressure-sensitive resistor R3 and a second input end of the acoustic wave transmitting module 3.

In this solution, with the full-bridge piezoresistive structure as the second circuit structure and the pressure-sensitive resistors as long straight light-doped piezoresistive rods, the design principle of the above structure is further described.

With reference to FIG. 3, it shows a structural schematic diagram illustrating a pressure-sensitive sensing module in the present disclosure. When a pressure F acts on the second piezoelectric film 21 to deform, the first pressure-sensitive resistor R1 and the fourth pressure-sensitive resistor R4 as long straight light-doped piezoresistive rods may deform to be longer, and the corresponding resistance value is increased by ΔR; and the second pressure-sensitive resistor R2 and the third pressure-sensitive resistor R3 as long straight light-doped piezoresistive rods may deform to be wider and based on piezoresistive effect theory, since its relative deformation variable of widening is equal to the above relative deformation variable of lengthening, the resistance value is also increased by ΔR.

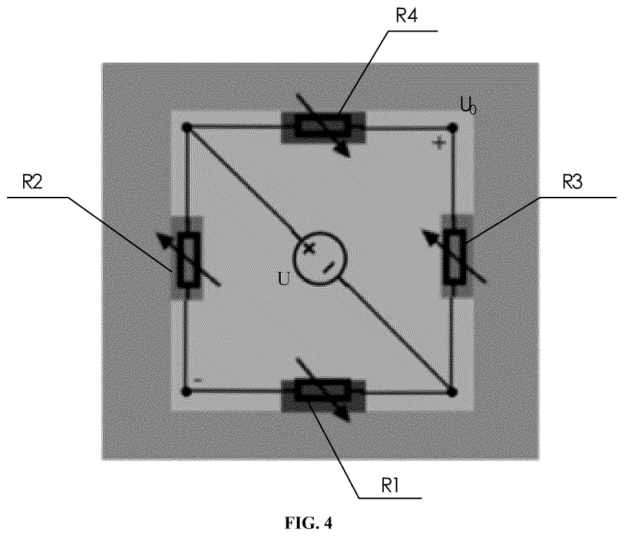

With reference to FIG. 4, it is an equivalent circuit diagram illustrating a full-bridge piezoresistive structure in the present disclosure. It is supposed that the first electrical signal corresponds to an input voltage U, the second electrical signal corresponds to an output voltage U₀, the resistance value of the first pressure-sensitive resistor R1 is R₁, the resistance value of the second pressure-sensitive resistor R2 is R₂, the resistance value of the third pressure-sensitive resistor R3 is R₃, and the resistance value of the fourth pressure-sensitive resistor R4 is R₄. Based on the circuit structure, the following expression can be obtained:

$$\begin{matrix}{U}_{0} = ( \frac{{R}_{4}}{{R}_{2} + {R}_{4}} - \frac{{R}_{3}}{{R}_{1} + {R}_{3}} ) U \\ = \frac{( {R}_{1} {R}_{4} - {R}_{1} {R}_{4} )}{( {R}_{2} + {R}_{4} ) ( {R}_{1} + {R}_{3} )} U\end{matrix}$$

In an ideal circumstance, the resistance value R₁ of the first pressure-sensitive resistor R1=the resistance value R₂ of the second pressure-sensitive resistor R2=the resistance value R₃ of the third pressure-sensitive resistor R3=the resistance value R₄ of the fourth pressure-sensitive resistor R4=R; in this case, when the pressure-sensitive sensing module is not under pressure, the output voltage U₀=0; based on piezoresistive effect, when a pressure acts on the second piezoelectric film 21, the resistivity of each pressure-sensitive resistor may change and the corresponding resistance value also change. If the first pressure-sensitive resistor R1 and the fourth pressure-sensitive resistor R4 are in a positive stress zone, the resistance value R₁ of the first pressure-sensitive resistor R1 changes into R₁+ΔR₁, and the resistance value R₄ of the fourth pressure-sensitive resistor R4 changes into R₄+ΔR₄; when second pressure-sensitive resistor R2 and the third pressure-sensitive resistor R3 are in a negative stress zone, the resistance value R₂ of the second pressure-sensitive resistor R2 changes into R₂−ΔR₂, and the resistance value R₃ of the third pressure-sensitive resistor R3 changes into R₃−ΔR₃. In ideal circumstance, ΔR₁=ΔR₃=ΔR₂=ΔR₄=ΔR and under pressure, the output voltage U₀ is expressed as follows:

$$\begin{matrix}{U}_{0} = ( \frac{{R}_{4} + Δ {R}_{4}}{{R}_{2} - Δ {R}_{2} + Δ {R}_{4} + {R}_{4}} - \frac{{R}_{3} - Δ {R}_{3}}{{R}_{1} + Δ {R}_{1} - Δ {R}_{3} + {R}_{3}} ) U \\ = ( \frac{R + Δ R}{2 R} - \frac{R - Δ R}{2 R} ) U \\ = \frac{Δ R}{R} U\end{matrix}$$

It can be seen that under the full-bridge piezoresistive structure, the second electrical signal (i.e. the above output voltage U₀) output by a pressure-sensitive module is directly proportional to piezoresistive relative change. Under the pressure inside the cell, the second piezoelectric film 21 generates strain which enables the resistance value of each pressure-sensitive resistor in the full-bridge piezoresistive structure to change and the output voltage U₀ to change (the output voltage U₀ is positively correlated with the received pressure). In this case, the in-situ pressure state inside the cell is coupled to the first electrical signal to obtain the second electrical signal.

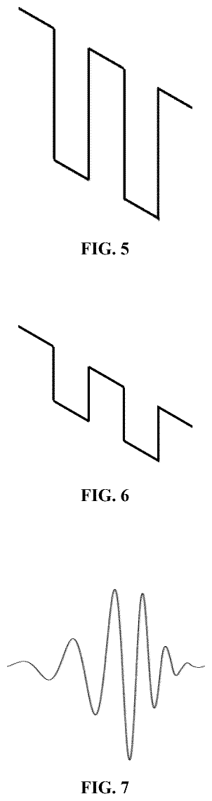

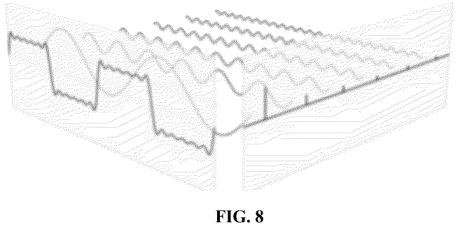

As a further description to the above embodiments, FIG. 5 shows a simplified diagram illustrating the first acoustic wave signal in the present disclosure. The external acoustic wave transmitter transmits an ultrasonic square wave signal (i.e. first acoustic wave signal) consistent with the first-order mode resonant frequency of the first piezoelectric film in the acoustic wave receiving module 1, and the acoustic wave receiving module 1 performs acoustic-electric signal conversion to obtain the first electrical signal and inputs the first electrical signal into the working condition sensing module 2. The working condition sensing module 2 is the above pressure-sensitive module which uses the above full-bridge piezoresistive structure as an example. The second electrical signal output by the output end of the pressure-sensitive module is positively correlated with the pressure received by it. The second electrical signal is specifically a square wave voltage signal. As shown in FIG. 6, it is a simplified diagram illustrating the second electrical signal in the present disclosure. The first-order mode resonant frequency of the third piezoelectric film in the acoustic wave transmitting module 3 is different from the first-order mode resonant frequency of the first piezoelectric film, and the first-order mode resonant frequency of the third piezoelectric film is the second preset resonant frequency. Electric-acoustic signal conversion is performed on the electrical signal component corresponding to the second preset resonant frequency in the square wave voltage signal of the output end of the pressure-sensitive module to transmit the second acoustic wave signal, realizing selective output of the harmonic wave. As shown in FIG. 7, it is a simplified diagram illustrating a second acoustic wave signal in the present disclosure. The external acoustic wave receiver may, based on the second acoustic wave signal, determine the in-situ working state of the cell, so as to realize measurement on the in-situ working state of the cell in the lithium battery.

It is further noted that the principle on which the acoustic wave transmitting module 3 perform electric-acoustic signal conversion only on the electrical signal component satisfying the second preset resonant frequency in the second electrical signal is further described based on Fourier Transform. The given square wave signal f(t), time domain signal and Fourier series expansion are described respectively as follows: the period is T, the frequency is f, the corresponding angular frequency is

$$ω = 2 π f = \frac{2 π}{T} ,$$

E is the signal amplitude, and n is a number of expanded items.

$$f ( t ) = \{ \begin{matrix}- \frac{E}{2} & - T / 2 \leq t < 0 \\ \frac{E}{2} & 0 \leq t \leq T / 2\end{matrix}$$

$$\begin{matrix}f ( t ) = \frac{4 E}{π} [ sin ( ω t ) + \frac{1}{3} sin ( 3 ω t ) + \frac{1}{5} sin ( 5 ω t ) + … ] \\ = \frac{4 E}{π} {\sum }_{n = 0}^{∞} \frac{sin ( ( 2 n + 1 ) ω t )}{2 n + 1}\end{matrix}$$

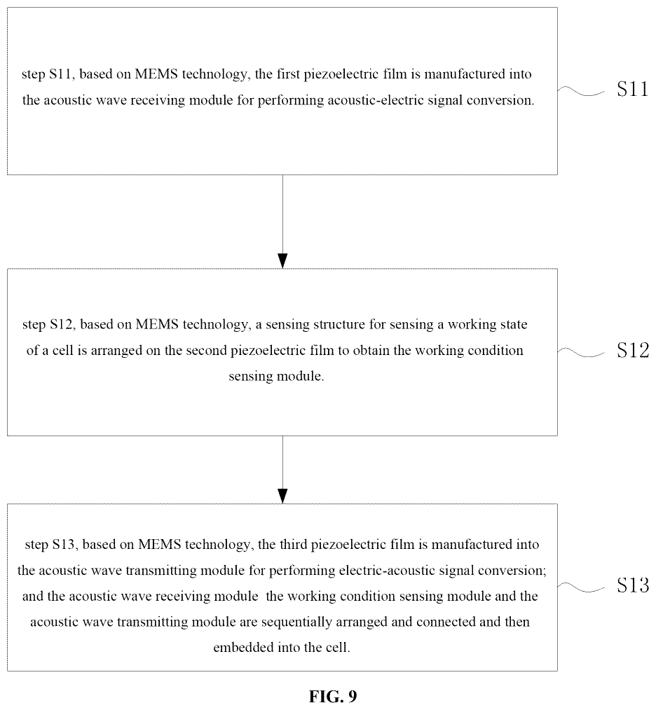

As shown in FIG. 8, it is a schematic diagram illustrating a harmonic superimposition of a square wave signal in the present disclosure. It can be seen that the square wave signal is obtained by superimposition of a series of sine and cosine harmonic waves with different amplitudes, which proves that the second electrical signal is generated by superimposition of electrical signal components with different resonant frequencies. The acoustic wave transmitting module 3 can perform electric-acoustic signal conversion only on the electrical signal component satisfying the second preset resonant frequency in the second electrical signal.

With reference to FIG. 9, it is a flowchart illustrating a manufacturing method of a wireless microsystem for performing real-time monitoring on in-situ pressure and temperature inside a lithium battery according to the present disclosure.

The manufacturing method of the wireless microsystem for performing real-time monitoring on in-situ pressure and temperature inside the lithium battery is used to manufacture the above wireless microsystem for performing real-time monitoring on in-situ pressure and temperature inside the lithium battery. The method includes the following steps.

At step S11, based on MEMS technology, the first piezoelectric film is manufactured into the acoustic wave receiving module 1 for performing acoustic-electric signal conversion.

At step S12, based on MEMS technology, a sensing structure for sensing a working state of a cell is arranged on the second piezoelectric film to obtain the working condition sensing module 2.

At step S13, based on MEMS technology, the third piezoelectric film is manufactured into the acoustic wave transmitting module 3 for performing electric-acoustic signal conversion; and the acoustic wave receiving module 1, the working condition sensing module 2 and the acoustic wave transmitting module 3 are sequentially arranged and connected and then embedded into the cell.

For the descriptions of the manufacturing method of the wireless microsystem for performing real-time monitoring on in-situ pressure and temperature inside the lithium battery in the present disclosure, reference can be made to the embodiments of the above wireless microsystem for performing real-time monitoring on in-situ pressure and temperature inside the lithium battery and no redundant descriptions are made herein.

Although descriptions are made as above, the scope of protection of the preset disclosure is not limited hereto. Those skilled in the arts can, without departing from the spirit and scope of the present disclosure, make various changes and modifications and such changes and modifications shall all fall within the scope of protection of the present disclosure.

It is further noted that in the present specification, the relational terms such as first and second and so on are used only to distinguish one entity or operation from another entity or operation and do not imply presence of any actual relationship or sequence among these entities or operations.

What is claimed:

1. A wireless microsystem for performing real-time monitoring on in-situ pressure and temperature inside a lithium battery, wherein the system is applied inside a cell, and the wireless microsystem for performing real-time monitoring on in-situ pressure and temperature inside the lithium battery comprises an acoustic wave receiving module (1), a working condition sensing module (2), and an acoustic wave transmitting module (3) manufactured based on Micro-Electro-Mechanical System (MEMS) technology;
the acoustic wave receiving module (1), the working condition sensing module (2) and the acoustic wave transmitting module (3) are sequentially connected;
the acoustic wave receiving module (1) is configured to, based on a first acoustic wave signal received from an external acoustic wave transmitter and corresponding to a first preset resonant frequency, perform acoustic-electric signal conversion to obtain a first electrical signal;
the working condition sensing module (2) is configured to couple an in-situ working state inside the cell to the first electrical signal to obtain a second electrical signal;
the acoustic wave transmitting module (3) is configured to perform electric-acoustic signal conversion on an electrical signal component satisfying a preset resonant frequency in the second electrical signal to transmit a second acoustic wave signal such that an external acoustic wave receiver determines the in-situ working state based on the received second acoustic wave signal, and the first preset resonant frequency is different from the second preset resonant frequency.

2. The wireless microsystem for performing real-time monitoring on in-situ pressure and temperature inside a lithium battery of claim 1, wherein the acoustic wave receiving module (1) is an acoustic wave transducer which comprises structural subunits (11), and the structural subunits (11) comprise an upper electrode layer, a first piezoelectric film (111) and a lower electrode layer arranged sequentially from top down;
the second preset resonant frequency is determined based on a geometric size of the first piezoelectric film (111) and a thickness of the structural subunits (11) such that the second preset resonant frequency is different from the first preset resonant frequency.

3. The wireless microsystem for performing real-time monitoring on in-situ pressure and temperature inside a lithium battery of claim 2, wherein the structural subunits are connected sequentially to form an array structure of N*M; N is an integer greater than 1 and M is an integer greater than 1, and N*M=a total number of the structural subunits.

4. The wireless microsystem for performing real-time monitoring on in-situ pressure and temperature inside a lithium battery of claim 2, wherein the first acoustic wave signal is an acoustic wave signal consistent with a first-order mode resonant frequency of the first piezoelectric film (111).

5. The wireless microsystem for performing real-time monitoring on in-situ pressure and temperature inside a lithium battery of claim 1, wherein the working condition sensing module (2) comprises a second piezoelectric film (21) and a pressure-sensitive sensing module arranged on the second piezoelectric film (21) to sense the in-situ pressure condition inside the cell, and/or, a heat-sensitive sensing module to sense the in-situ temperature condition inside the cell; and when the working condition sensing module (2) comprises the pressure-sensitive sensing module and the heat-sensitive sensing module, the pressure-sensitive sensing module and the heat-sensitive sensing module are in parallel connection.

6. The wireless microsystem for performing real-time monitoring on in-situ pressure and temperature inside a lithium battery of claim 5, wherein the heat-sensitive sensing module comprises a first circuit structure formed by multiple heat-sensitive resistors with a resistance value changing along with the temperature inside the cell such that the second electrical signal can be changed along with the temperature inside the cell.

7. The wireless microsystem for performing real-time monitoring on in-situ pressure and temperature inside a lithium battery of claim 5, wherein the pressure-sensitive sensing module comprises a second circuit structure formed by multiple pressure-sensitive resistors with a resistance value changing along with the pressure inside the cell such that the second electrical signal can be changed along with the pressure inside the cell.

8. The wireless microsystem for performing real-time monitoring on in-situ pressure and temperature inside a lithium battery of claim 7, wherein the second circuit structure comprises a first pressure-sensitive resistor (R1), a second pressure-sensitive resistor (R2), a third pressure-sensitive resistor (R3) and a fourth pressure-sensitive resistor (R4);
an end of the first pressure-sensitive resistor (R1) is respectively connected to an end of the second pressure-sensitive resistor (R2) and a first input end of the acoustic wave transmitting module (3), and the other end of the first pressure-sensitive resistor (R1) is respectively connected to an end of the third pressure-sensitive resistor (R3) and a first output end of the acoustic wave receiving module (1);
the other end of the second pressure-sensitive resistor (R2) is respectively connected to an end of the fourth pressure-sensitive resistor (R4) and a second output end of the acoustic wave receiving module (1), and the other end of the fourth pressure-sensitive resistor (R4) is respectively connected to the other end of the third pressure-sensitive resistor (R3) and a second input end of the acoustic wave transmitting module (3).

9. A manufacturing method of a wireless microsystem for performing real-time monitoring on in-situ pressure and temperature inside a lithium battery, comprising:
based on MEMS technology, manufacturing an acoustic wave receiving module (1) for performing acoustic-electric signal conversion by using a first piezoelectric film;
based on MEMS technology, arranging a sensing structure for sensing a working state of a cell on a second piezoelectric film to obtain a working condition sensing module (2);
based MEMS technology, manufacturing an acoustic wave transmitting module (3) for performing electric-acoustic signal conversion by using a third piezoelectric film and arranging and connecting the acoustic wave receiving module (1), the working condition sensing module (2) and the acoustic wave transmitting module (3) sequentially and then embedding into the cell.
